(19) United States
(12) Patent Application Publication
(10) Pub. No.: US 2026/0173895 A1
(43) Pub. Date: Jun. 18, 2026

(54) PACKAGE STRUCTURE AND METHOD OF FORMING THE SAME

(71) Applicant: Taiwan Semiconductor Manufacturing Company, Ltd., Hsinchu (TW)

(72) Inventors: Jia-Kuen Wang, Hsinchu City (TW); Kuo-Chiang Ting, Hsinchu City (TW); Sung-Feng Yeh, Taipei City (TW); Shun-Jang Liao, Taoyuan County (TW); Ta-Hao Sung, Yilan County (TW)

(73) Assignee: Taiwan Semiconductor Manufacturing Company, Ltd., Hsinchu (TW)

(21) Appl. No.: 18/977,944

(22) Filed: Dec. 12, 2024

(51) Int. Cl. H01L 23/544; H01L 23/00; H01L 25/11

(52) U.S. Cl. CPC H10W 46/00; H10W 90/00; H10W 46/301; H10W 72/07323; H10W 72/07331; H10W 90/701; H10W 90/732

(57) ABSTRACT

Provided is a package structure including a middle layer having a first surface and a second surface opposite to each other, a first die, and a second die. The middle layer includes a plurality of metal features. The first die is disposed on the first surface of the middle layer, wherein the first die includes a plurality of first bonding pads respectively contacting the plurality of metal features at the first surface to define a first bonding interface. The second die is disposed on the second surface of the middle layer, wherein the second die includes a plurality of second bonding pads respectively contacting the plurality of metal features at the second surface to define a second bonding interface.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 9 illustrate cross-sectional views of intermediate stages in the formation of a package structure in accordance with some embodiments.

FIG. 10A and FIG. 10B illustrate enlarged cross-sectional views of a region of a package structure of FIG. 9 in accordance with various embodiments.

FIG. 11 illustrates a cross-sectional view of a package structure in accordance with some alternative embodiments.

FIG. 12 illustrates a cross-sectional view of a package structure in accordance with some other embodiments.

FIG. 13 illustrates a cross-sectional view of a package structure in accordance with some alternative embodiments.

FIG. 14 illustrates a cross-sectional view of a package structure in accordance with some other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

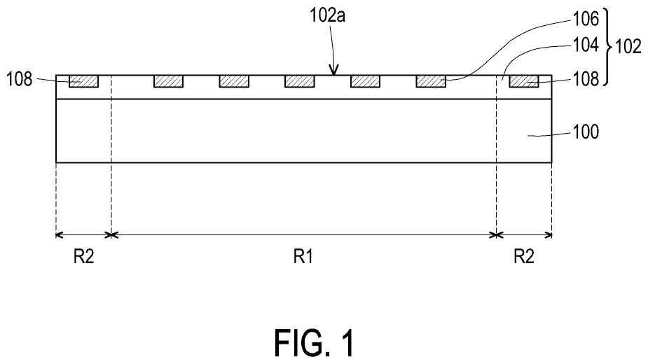

FIG. 1 to FIG. 9 illustrate cross-sectional views of intermediate stages in the formation of a package structure in accordance with some embodiments.

Referring to FIG. 1, a first carrier 100 (also referred to as a first substrate) is provided or formed. The first carrier 100 is used as a platform or a support for a packaging process described below. In some embodiments, the first carrier 100 comprises a semiconductor material (such as silicon, or the like), a dielectric material (such as glass, a ceramic material, quartz, or the like), a combination thereof, or the like.

In some embodiments, a middle layer 102 may be formed on the first carrier 100. Specifically, the middle layer 102 may include a dielectric layer 104 and a plurality of metal features 105 formed in the dielectric layer 104. In some embodiments, the dielectric layer 104 includes silicon oxide, silicon oxynitride, silicon nitride, low dielectric constant (low-k) materials or a combination thereof. The low-k dielectric materials may have dielectric constant values (k-value) lower than 3.8, and the k-values may be lower than about 3.0 or about 2.5. The low-k dielectric layers may be formed of a carbon-containing low-k dielectric material, Hydrogen SilsesQuioxane (HSQ), MethylSilsesQuioxane (MSQ), or the like. In some alternatively embodiments, the dielectric layer 104 may be a single layer or multiple layers.

The metal features 105 may include a plurality of bonding metal layers 106 and alignment marks 108. In detail, the middle layer 102 may be divided into a die attach region R1 and a peripheral region R2 surrounding the die attach region R1. The die attach region R1 may be defined as a region that is used to subsequently attach one or more bottom dies 110 onto the middle layer 102, while the peripheral region R2 may be defined as a region that does not have any die attached thereto. In this case, the peripheral region R2 may be referred to as non-die attach region. As show in FIG. 1, the bonding metal layers 106 may be formed within the die attach region R1, and the alignment marks 108 may be formed within the peripheral region R2 for subsequent alignment and bonding. The bonding metal layers 106 and the alignment marks 108 may be exposed by the dielectric layer 104 at a first surface 102a. In some embodiments, the metal features 105 may be made of tungsten (W), copper (Cu), copper alloys, aluminum (Al), aluminum alloys, or a combination thereof, and may be formed by a single damascene process. In some embodiments, a barrier layer (not shown in FIG. 1) may be formed to conformally cover a sidewall and a bottom surface of the metal feature 105. A material of the barrier layer includes tantalum, tantalum nitride, titanium, titanium nitride, cobalt-tungsten (CoW) or a combination thereof, for example.

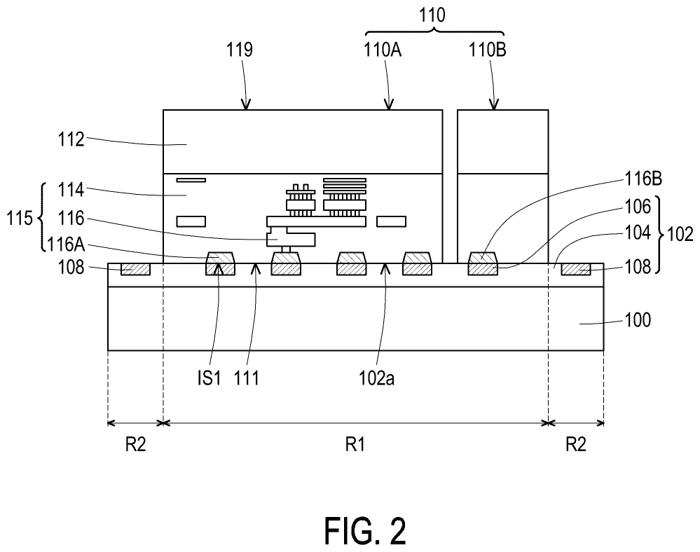

Referring to FIG. 2, one or more bottom dies 110 may be bonded onto the first surface 102a of the middle layer 102 within the die attach region R1. In some embodiments, the bottom dies 110 may include a first die 110A and a dummy die 110B arranged side by side. In some embodiments, the first die 110A may be a logic die (e.g., central processing unit, mobile application processor, ASIC, GPU, FPGA, microcontroller, etc.), a memory die (e.g., dynamic random access memory (DRAM) die, a Wide I/O die, a M-RAM die, a R-RAM die, a NAND die, a static random access memory (SRAM) die, etc.), a memory cube (e.g., HBM, HMC, etc.), a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, signal processing dies (e.g., digital signal processing (DSP) die), a front-end die (e.g., analog front-end (AFE) dies), a monolithic 3D heterogeneous chiplet stacking die, the like, or a combination thereof.

Specifically, the first die 110A may include a first semiconductor substrate 112 and a first interconnect structure 115 over the first semiconductor substrate 112. In some embodiments, the first semiconductor substrate 112 may include silicon or other semiconductor materials, such as a silicon or semiconductor wafer. Alternatively, or additionally, the first semiconductor substrate 112 may include other elementary semiconductor materials such as germanium. In some embodiments, the first semiconductor substrate 112 is made of a compound semiconductor such as silicon carbide, gallium arsenic, indium arsenide or indium phosphide. In some embodiments, the first semiconductor substrate 112 is made of an alloy semiconductor such as silicon germanium, silicon germanium carbide, gallium arsenic phosphide, or gallium indium phosphide. In some embodiments, the first semiconductor substrate 112 includes an epitaxial layer. For example, the first semiconductor substrate 112 has an epitaxial layer overlying a bulk semiconductor substrate. In other embodiments, the first semiconductor substrate 112 may be an interposer.

In some embodiments, the first interconnect structure 115 may be formed over the first semiconductor substrate 112. In detail, the first interconnect structure 115 includes a first insulating material 114 and a plurality of first metallization layers 116. The first metallization layers 116 are formed in the first insulating material 114 and electrically connected to each other. In some embodiments, the first insulating material 114 includes an interlayer dielectric (ILD) layer on the first semiconductor substrate 112, and at least one inter-metal dielectric (IMD) layer over the inner-layer dielectric layer. In some embodiments, the first insulating material 114 includes silicon oxide, silicon oxynitride, silicon nitride, low dielectric constant (low-k) materials or a combination thereof. In some alternatively embodiments, the first insulating material 114 may be a single layer or multiple layers. In some embodiments, the first metallization layers 116 include plugs and metal lines. The plugs may include contacts formed in the ILD layer, and vias formed in the IMD layer. The contacts are formed between and in contact with the substrate 112 and a bottom metal line. The vias are formed between and in contact with two metal lines. The first metallization layers 116 may be made of tungsten (W), copper (Cu), copper alloys, aluminum (Al), aluminum alloys, or a combination thereof. In some alternatively embodiments, a barrier layer (not shown) may be formed between the first metallization layers 116 and the first insulating material 114 to prevent the material of the first metallization layers 116 from migration. A material of the barrier layer includes tantalum, tantalum nitride, titanium, titanium nitride, cobalt-tungsten (CoW) or a combination thereof, for example.

In addition, the first device region (not shown) may be formed between the first semiconductor substrate 112 and the first interconnect structure 115 by a front-end-of-line (FEOL) process. The first device region includes a wide variety of devices. In some embodiments, the devices comprise active components, passive components, or a combination thereof. In some embodiments, the devices may include integrated circuits devices. The devices are, for example, transistors, capacitors, resistors, diodes, photodiodes, fuse devices, or other similar devices. In some embodiments, the first device region includes a gate structure, source/drain regions, and isolation structures, such as shallow trench isolation (STI) structures. The said first device region is merely an example, while other structures may be formed in the first device region. In the first device region, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed on the first semiconductor substrate 112. The functions of the devices may include memory, processors, sensors, amplifiers, power distribution, input/output circuitry, or the like.

As shown in FIG. 2, an outermost metallization layer 116 exposed by the first insulating material 114 at a frontside 111 of the first die 110A may be referred to as first bonding pads 116A. The first bonding pads 116A may be respectively in contact with the bonding metal layers 106 at the first surface 102a to define a first bonding interface IS1. In detail, the first die 110A may be flipped upside down so that a backside 119 (sometimes called an inactive surface) of the first die 110A faces up and the frontside 111 (sometimes called an active surface) of the first die 110A faces toward the first surface 102a of the middle layer 102.

In some embodiments, before the first die 110A is bonded to the first surface 102a of the middle layer 102, the first bonding pads 116A are aligned with the bonding metal layers 106 respectively. In some embodiments, the alignment of the first bonding pads 116A and the bonding metal layers 106 may be achieved by using the alignment marks 108. Specifically, the alignment marks 108 may be used to determine the relative position of the first die 110A with respect to the middle layer 102, so that the first bonding pads 116A may be aligned with the bonding metal layers 106. After the alignment is achieved, the first die 110A and the middle layer 102 are bonded together by a direct bonding. The first die 110A and the middle layer 102 are directly bonded together by the application of pressure and heat. It is understood that the direct bonding involves at least two types of bonding, including metal-to-metal bonding and non-metal-to-non-metal bonding such as dielectric-to-dielectric bonding or fusion bonding. For example, as shown in FIG. 2, the first bonding pads 116A may be bonded to the bonding metal layers 106 by metal-to-metal bonding. On the other hand, an outermost portion of the first insulating material 114 may be bonded to a portion of the dielectric layer 104 by non-metal-to-non-metal bonding. In this case, the plane including the contact surface of the first bonding pads 116A (directly) contacting the bonding metal layers 106 and the contact surface of the outermost portion of the first insulating material 114 (directly) contacting the respective portion of the dielectric layer 104 is defined as the first bonding interface IS1. In some embodiments, the first bonding interface IS1 may be substantially level with the frontside 111 of the first die 110A and the first surface 102a of the middle layer 102.

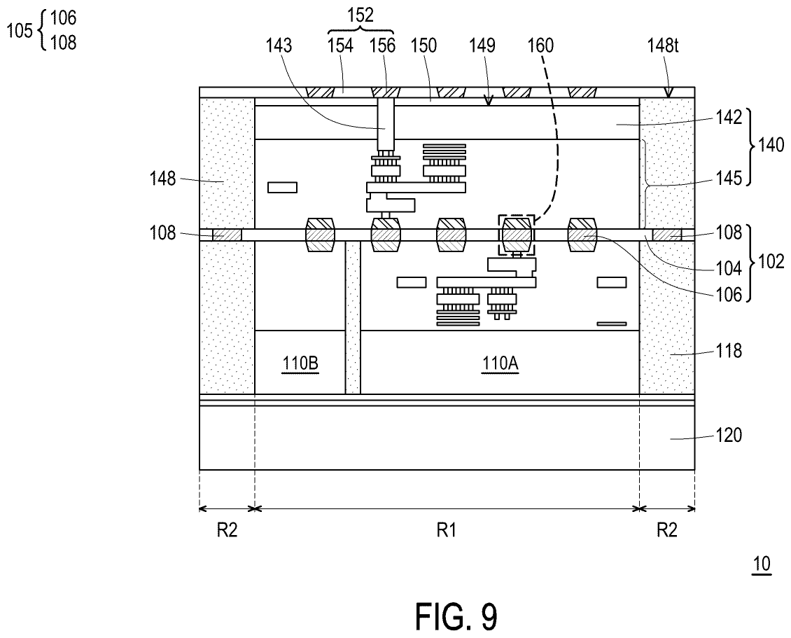

Similarly, the dummy die 110B may be bonded to the first surface 102a of the middle layer 102 within the die attach region R1. The dummy die 110B may include a plurality of bonding pads 116B respectively contacting the bonding metal layers 106 at the first bonding interface IS1. The dummy die 110B may be free of active and/or passive devices, and thus may be considered “dummy die” in the present embodiment. In some embodiments, the dummy die 110B may include one or more materials having a suitably high thermal conductivity. For example, the dummy die 110B may include a material such as silicon (e.g., bulk silicon), silicon oxide, silicon carbine, aluminum nitride, a ceramic material, the like, or a combination thereof. In such embodiment, the dummy die 110B may be referred to as heat sink or heat dissipation structure for facilitating the dissipation of heat from the subsequently formed second die 140 (FIG. 9).

After bonding the bottom dies 110 onto the first surface 102a of the middle layer 102, the bonding metal layers 106 may be covered by the bottom dies 110 while the alignment marks 108 within the peripheral region R2 are exposed. Although two alignment marks 108 are illustrated in FIG. 2, the embodiments of the present invention are not limited thereto. At least one alignment mark 108 can achieve the purpose of aligning the bottom dies 110 with the middle layer 102, so the present disclosure does not limit the number of the alignment marks 108.

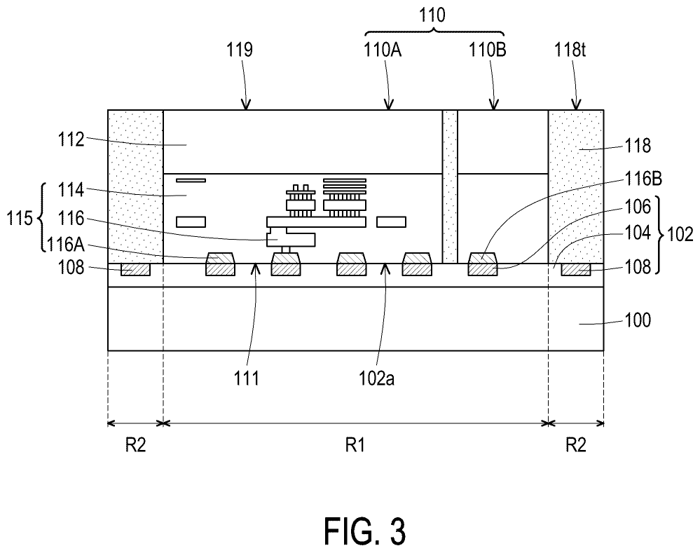

Referring to FIG. 3, a first filling material 118 may be formed on the first surface 102a of the middle layer 102 to laterally encapsulate the bottom dies 110. More specifically, the first filling material 118 is formed around the bottom dies 110 and covers the backside 119 of the first die 110A. The first filling material 118 may be formed by firstly forming a gap-filling material (not shown) over and covering the bottom dies 110. Thereafter, the gap-filling material over the bottom dies 110 is removed by a planarization process, such as a CMP process. In some embodiments, a portion of the gap-filling material is removed, so that the backside 119 of the first die 110A is exposed. In the case, the backside 119 of the first die 110A is substantially level with a top surface 118t of the first filling material 118. In addition, a portion of the bottom dies 110 (e.g., the first semiconductor substrate 112) is also removed to reduce the thickness of the bottom dies 110.

In some embodiments, the first filling material 118 includes an inorganic dielectric, which may be an oxide-based dielectric, such as silicon oxide. For example, the silicon oxide may be formed of tetraethoxysilane (TEOS). The forming method may include Chemical Vapor Deposition (CVD), High-Density Plasma Chemical Vapor Deposition (HDPCVD), or the like. In some alternative embodiments, the first filling material 118 includes a molding compound, a molding underfill, a resin such as epoxy, a combination thereof, or the like. The forming method of the first filling material 118 includes a molding process, a molding underfilling (MUF) process, or a combination thereof.

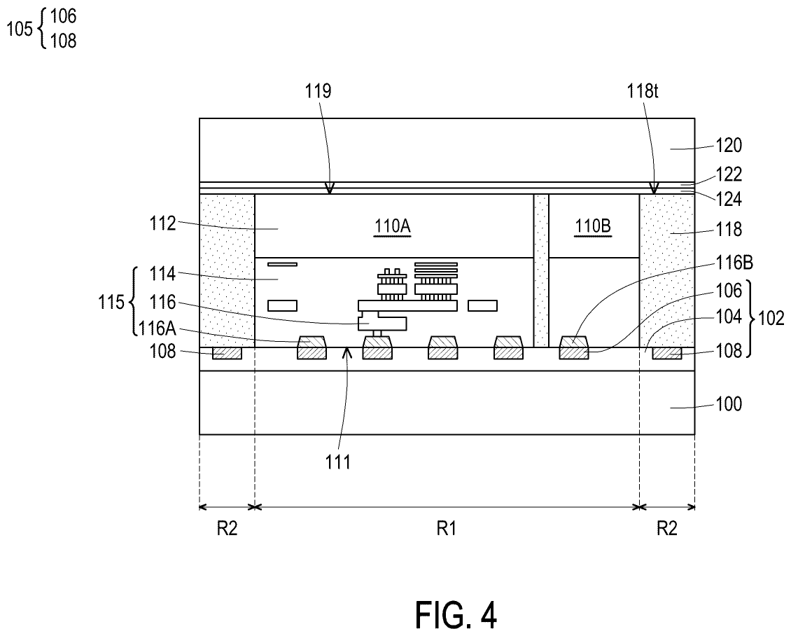

Referring to FIG. 4, a second carrier 120 (also referred to as a second substrate) is bonded to the backside 119 of the first die 110A and the top surface 118t of the first filling material 118. Specifically, the second carrier 120 may be bonded to the bottom dies 110 by contacting a bonding dielectric layer 122 with another bonding dielectric layer 124. The bonding dielectric layer 122 may be formed on the second carrier 120. The bonding dielectric layer 124 may be formed to cover the bottom dies 110 and the first filling material 118. In some embodiments, the bonding dielectric layers 122 and 124 may include a dielectric material, such as silicon oxide, aluminum oxide, silicon nitride, silicon oxynitride, silicon carbide, silicon oxycarbide, silicon carbonitride, silicon oxycarbonitride, a combination thereof, or the like. The bonding dielectric layers 122 and 124 may have the same dielectric material or different dielectric materials. The bonding of the bonding dielectric layer 122 to the bonding dielectric layer 124 may be achieved through fusion bonding, for example, with Si—O—Si bonds being formed to join bond the bonding dielectric layer 122 to the bonding dielectric layer 124. Other bonds may be formed to join bond the bonding dielectric layer 122 to the bonding dielectric layer 124, such as Si—N—Si bonds.

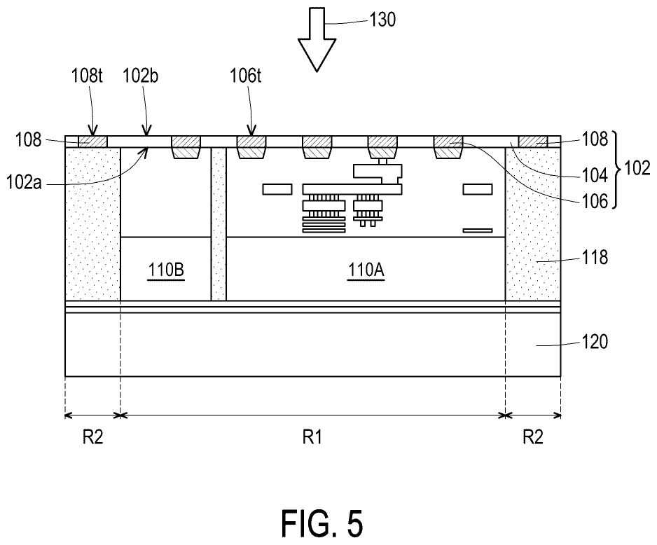

Referring to FIG. 4 and FIG. 5, a removal process 130 may be performed to remove the first carrier 100 and a portion of the dielectric layer 104 of the middle layer 102. In this case, the metal features 105 of the middle layer 102 may be exposed at a second surface 102b of the middle layer 102 opposite to the first surface 102a. In some embodiments, the removal process 130 may include at least two removal steps. Specifically, a first removal step may be a wet etching process to completely remove the first carrier 100, and a second removal step may be a CMP process to remove a portion of the dielectric layer 104 until exposing the metal features 105. In this case, the second surface 102b of the middle layer 102 may be substantially level with the top surface 106t of the bonding metal layers 106 and the top surface 108t of the alignment marks 108, as shown in FIG. 5.

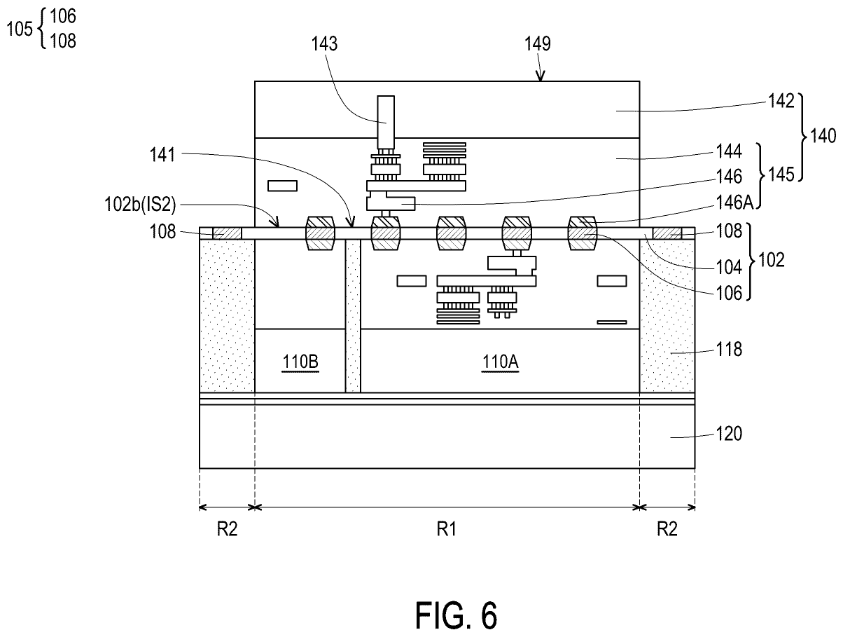

Referring to FIG. 6, a second die 140 may be bonded onto the second surface 102b of the middle layer 102 within the die attach region R1. In some embodiments, the second die 140 may be a logic die (e.g., central processing unit, mobile application processor, ASIC, GPU, FPGA, microcontroller, etc.), a memory die (e.g., dynamic random access memory (DRAM) die, a Wide I/O die, a M-RAM die, a R-RAM die, a NAND die, a static random access memory (SRAM) die, etc.), a memory cube (e.g., HBM, HMC, etc.), a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, signal processing dies (e.g., digital signal processing (DSP) die), a front-end die (e.g., analog front-end (AFE) dies), a monolithic 3D heterogeneous chiplet stacking die, the like, or a combination thereof. The first die 110A and the second die 140 may different functions or the same function. In the present embodiment, the second die 140 may have a lateral width greater than a lateral width of the first die 110A. For example, the first die 110A and the dummy die 110B may be within a span of the second die 140 (which is measured by the opposite sidewalls of the second die 140), as shown in FIG. 6.

Specifically, the second die 140 may include a second semiconductor substrate 142 and a second interconnect structure 145 over the second semiconductor substrate 142. In some embodiments, the second semiconductor substrate 142 may include silicon or other semiconductor materials, such as a silicon or semiconductor wafer. Alternatively, or additionally, the second semiconductor substrate 142 may include other elementary semiconductor materials such as germanium. In some embodiments, the second semiconductor substrate 142 is made of a compound semiconductor such as silicon carbide, gallium arsenic, indium arsenide or indium phosphide. In some embodiments, the second semiconductor substrate 142 is made of an alloy semiconductor such as silicon germanium, silicon germanium carbide, gallium arsenic phosphide, or gallium indium phosphide. In some embodiments, the second semiconductor substrate 142 includes an epitaxial layer. For example, the second semiconductor substrate 142 has an epitaxial layer overlying a bulk semiconductor substrate. In other embodiments, the second semiconductor substrate 142 may be an interposer.

In some embodiments, the second interconnect structure 145 may be formed over the second semiconductor substrate 142. In detail, the second interconnect structure 145 includes a second insulating material 144 and a plurality of second metallization layers 146. The second metallization layers 146 are formed in the second insulating material 144 and electrically connected to each other. In some embodiments, the second insulating material 144 includes an interlayer dielectric (ILD) layer on the second semiconductor substrate 142, and at least one inter-metal dielectric (IMD) layer over the inner-layer dielectric layer. In some embodiments, the second insulating material 144 includes silicon oxide, silicon oxynitride, silicon nitride, low dielectric constant (low-k) materials or a combination thereof. In some alternatively embodiments, the second insulating material 144 may be a single layer or multiple layers. In some embodiments, the second metallization layers 146 include plugs and metal lines. The plugs may include contacts formed in the ILD layer, and vias formed in the IMD layer. The contacts are formed between and in contact with the substrate 142 and a bottom metal line. The vias are formed between and in contact with two metal lines. The second metallization layers 146 may be made of tungsten (W), copper (Cu), copper alloys, aluminum (Al), aluminum alloys, or a combination thereof. In some alternatively embodiments, a barrier layer (not shown) may be formed between the second metallization layers 146 and the second insulating material 144 to prevent the material of the second metallization layers 146 from migration. A material of the barrier layer includes tantalum, tantalum nitride, titanium, titanium nitride, cobalt-tungsten (CoW) or a combination thereof, for example.

In addition, the second device region (not shown) is formed between the second semiconductor substrate 142 and the second interconnect structure 145 by a front-end-of-line (FEOL) process. The second device region includes a wide variety of devices. In some embodiments, the devices comprise active components, passive components, or a combination thereof. In some embodiments, the devices may include integrated circuits devices. The devices are, for example, transistors, capacitors, resistors, diodes, photodiodes, fuse devices, or other similar devices. In some embodiments, the second device region includes a gate structure, source/drain regions, and isolation structures, such as shallow trench isolation (STI) structures. The said second device region is merely an example, while other structures may be formed in the second device region. In the second device region, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed on the second semiconductor substrate 142. The functions of the devices may include memory, processors, sensors, amplifiers, power distribution, input/output circuitry, or the like.

As shown in FIG. 6, an outermost metallization layer 146 exposed by the second insulating material 144 at a frontside 141 of the second die 140 may be referred to as second bonding pads 146A. The second bonding pads 146A may be respectively in contact with the bonding metal layers at the second surface 102b to define a second bonding interface IS2. In detail, the second die 140 may be flipped upside down so that a backside 149 (sometimes called an inactive surface) of the second die 140 faces up and the frontside 141 (sometimes called an active surface) of the second die 140 faces toward the second surface 102b of the middle layer 102.

In some embodiments, before the second die 140 is bonded to the second surface 102b of the middle layer 102, the second bonding pads 146A are aligned with the bonding metal layers 106 respectively. In some embodiments, the alignment of the second bonding pads 146A and the bonding metal layers 106 may be achieved by using the alignment marks 108. Specifically, the alignment marks 108 may be used to determine the relative position of the second die 140 with respect to the middle layer 102, so that the second bonding pads 146A may be aligned with the bonding metal layers 106. In the present embodiment, the alignment marks 108 of the middle layer 102 between the first die 110A and the second die 140 can be reused for multiple alignments to simplify process steps and reduce costs. After the alignment is achieved, the second die 140 and the middle layer 102 are bonded together by a direct bonding. The second die 140 and the middle layer 102 are directly bonded together by the application of pressure and heat. It is understood that the direct bonding involves at least two types of bonding, including metal-to-metal bonding and non-metal-to-non-metal bonding such as dielectric-to-dielectric bonding or fusion bonding. For example, as shown in FIG. 6, the second bonding pads 146A may be bonded to the bonding metal layers 106 by metal-to-metal bonding. On the other hand, an outermost portion of the second insulating material 144 may be bonded to a portion of the dielectric layer 104 by non-metal-to-non-metal bonding. In this case, the plane including the contact surface of the second bonding pads 146A (directly) contacting the bonding metal layers 106 and the contact surface of the outermost portion of the second insulating material 144 (directly) contacting the respective portion of the dielectric layer 104 is defined as the second bonding interface IS2. In some embodiments, the second bonding interface IS2 may be substantially level with the frontside 141 of the second die 140 and the first surface 102a of the middle layer 102.

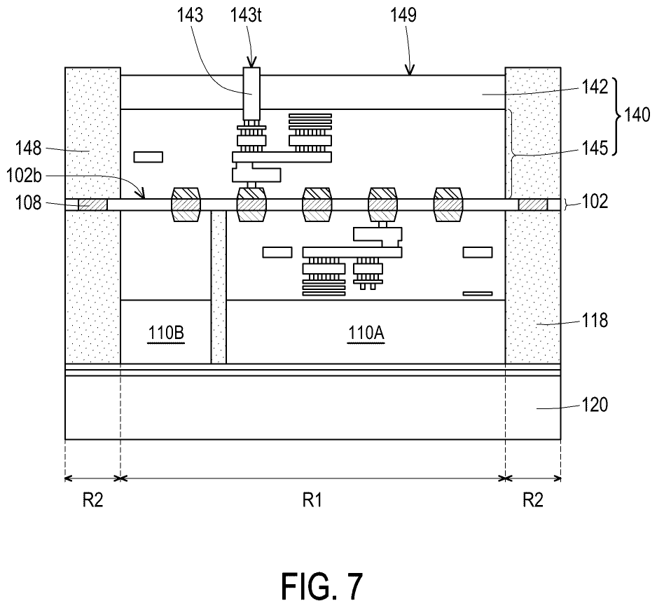

Referring to FIG. 7, a second filling material 148 may be formed on the second surface 102b of the middle layer 102 to laterally encapsulate the second die 140. More specifically, the second filling material 148 is formed around the second die 140 and covers the backside 149 of the second die 140. The second filling material 148 may be formed by firstly forming a gap-filling material (not shown) over and covering the second die 140. Thereafter, the gap-filling material over the second die 140 is removed by a planarization process, such as a CMP process. In some embodiments, portions of the gap-filling material and the second semiconductor substrate 142 are removed, so that the backside 149 of the second die 140 lowers until the via through-substrate via (TSV) 143 is exposed by a backside 149 of the second die 140. In the case, the TSV 143 may protrude from the backside 149 of the second die 140. However, the embodiments of the present invention are not limited thereto. In other embodiments, a top surface 143t of the TSV 143 may be substantially level with the backside 149 of the second die 140.

In some embodiments, the second filling material 148 includes an inorganic dielectric, which may be an oxide-based dielectric, such as silicon oxide. For example, the silicon oxide may be formed of tetraethoxysilane (TEOS). The forming method may include Chemical Vapor Deposition (CVD), High-Density Plasma Chemical Vapor Deposition (HDPCVD), or the like. In some alternative embodiments, the second filling material 148 includes a molding compound, a molding underfill, a resin such as epoxy, a combination thereof, or the like. The forming method of the second filling material 148 includes a molding process, a molding underfilling (MUF) process, or a combination thereof.

After forming the second filling material 148, the alignment marks 108 may be in contact with the first filling material 118 at the first surface 102a and in contact with the second filling material 148 at the second surface 102b. In some embodiments, the alignment marks 108 do not include vias extending into the first filling material 118 and the second filling material 148 to connect any conductive feature. That is, the alignment marks 108 are not electrically connected to any conductive feature. Accordingly, the alignment marks 108 are electrically floating. In addition, the alignment marks 108 may have any top-view shape for identify, and the embodiment of the present invention is not limited thereto.

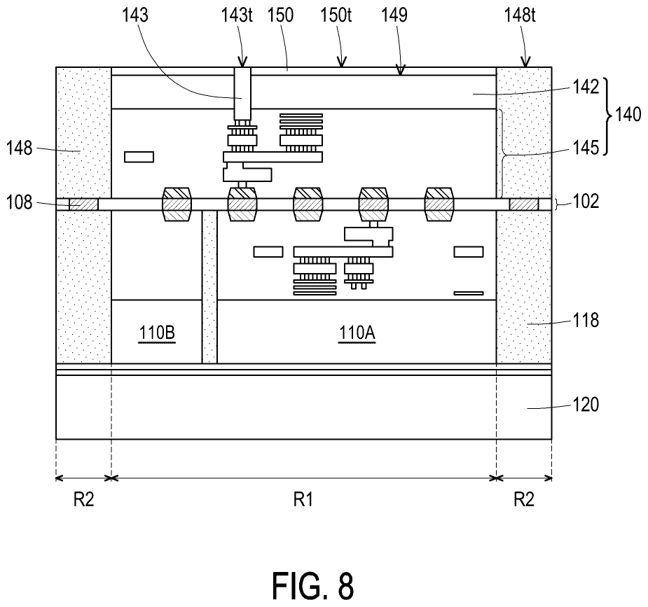

Referring to FIG. 8, a passivation layer 150 may be formed on the backside 149 of the second die 140 to laterally surround the upper portion of the TSV 143. Specifically, the passivation layer 150 may be formed by firstly forming a passivation material (not shown) over and covering the TSV 143, the backside 149 of the second die 140, and the second filling material 148. Thereafter, the passivation material over the TSV 143 is removed by a planarization process, such as a CMP process. In some embodiments, a portion of the passivation material is removed, so that the top surface 143t of the TSV 143 is exposed. In the case, the top surface 143t of the TSV 143 is substantially level with a top surface 150t of the passivation layer 150 and a top surface 148t of the second filling material 148. In some embodiments, the passivation layer 150 includes silicon oxide, silicon nitride, benzocyclobutene (BCB) polymer, polyimide (PI), polybenzoxazole (PBO) or a combination thereof and is formed by a suitable process such as spin coating, CVD or the like.

Referring to FIG. 9, a redistribution layer (RDL) structure 152 may be formed over the backside 149 of the second die 140 and the top surface 148t of the second filling material 148, thereby accomplishing a package structure 10. Specifically, the RDL structure 152 may include a dielectric layer 154 and a redistribution conductive layer 156 embedded in the dielectric layers 154. One portion of the redistribution conductive layer 156 may be electrically connected to the first die 110A via the TSV 143, the second interconnect structure 145 of the second die 140, and the metal features 105 of the middle layer 102. In some embodiments, the redistribution conductive layer 156 includes a plurality of traces and vias (not shown) stacked alternately. The redistribution conductive layer 156 may include metal, such as copper, aluminum, nickel, titanium, a combination thereof or the like.

Although only one RDL structure 152 is illustrated in FIG. 9, the embodiments of the present invention are not limited thereto. In some embodiments, one or more RDL structures are formed over the backside 149 of the second die 140 and the top surface 148t of the second filling material 148. That is, one or more dielectric layers and redistribution conductive layers formed in the one or more dielectric layers are included in the RDL structure 152. However, the layout or the arrangement of the RDL structures is not limited by the embodiments described herein.

Based on the above, the package structure 10 according to the present disclosure may include the middle layer 102 with more than one usage. Specifically, the bonding metal layers 106 of the middle layer 102 may allow the bottom dies 110 bonded onto the first surface 102a of the middle layer 102, and the second die 140 bonded onto the second surface 102b of the middle layer 102. Accordingly, the middle layer 102 may also be called a two-way bonding layer. In addition to bonding, the alignment marks 108 may be used to determine the relative position of the bottom dies 110/the second die 140 with respect to the middle layer 102 for alignment. That is, the step of aligning the bottom dies 110 to the middle layer 102 and the step of aligning the second die 140 to the middle layer 102 may use the same alignment marks 108 of the middle layer 102 to minimums the overlap shift issue, thereby improving the yield. In this case, the middle layer 102 may also be called a two-way aligned layer.

It will be apparent to people skilled in the art that the disclosure is not limited by the type of package used in the package structure. For all the package structures of the present disclosure, different types of packages (SoIC, CoWoS, InFO, PoP, etc.) may be applicable, according to the production and design requirements.

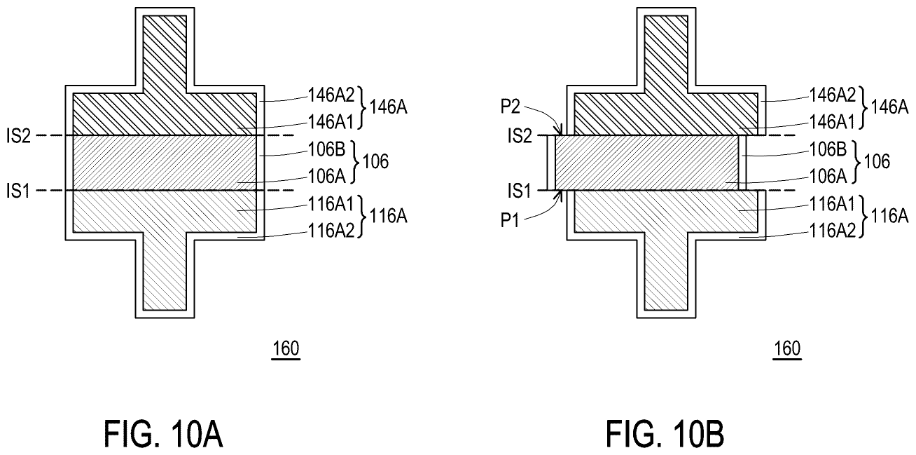

FIG. 10A and FIG. 10B illustrate enlarged cross-sectional views of a region 160 of a package structure of FIG. 9 in accordance with various embodiments.

Referring to FIG. 10A, the first bonding pads 116A may be respectively in contact with the bonding metal layers 106 of the metal features 105 at the first bonding interface IS1, and the second bonding pads 146A may be respectively in contact with the bonding metal layers 106 of the metal features 105 at the second bonding interface IS2. Specifically, one of the first bonding pads 116A may include a first metal layer 116A1 and a first barrier layer 116A2 covering and lining the surface of the first metal layer 116A1 except for the upper surface exposed at the first bonding interface IS1. In addition, one of the second bonding pads 146A may include a second metal layer 146A1 and a second barrier layer 146A2 covering and lining the surface of the second metal layer 146A1 except for the lower surface exposed at the second bonding interface IS2. Unlike the first and second bonding pads 116A and 146A is that, in some embodiments, one of the bonding metal layers 106 may include a metal layer 106A and a barrier layer 106B covering and lining a sidewall of the metal layer 106A without covering the upper surface of the metal layer 106A exposed at the second bonding interface IS2 and the lower surface of the metal layer 106A exposed at the first bonding interface IS1. That is, the barrier layer 106B only covers the sidewall of the metal layer 106A due to the CMP process of the removal process 130 illustrated in FIG. 5. In this case, the contact resistance at the first and second bonding interfaces IS1 and IS2 can be effectively reduced. In some embodiments, the metal layers 106A, 116A1, and 146A1 may include a metal material such as Cu, Ni, Au, W, copper alloys, Al, aluminum alloys, or a combination thereof, and the barrier layers 106B, 116A2, and 146A2 may include a barrier material such as tantalum, tantalum nitride, titanium, titanium nitride, cobalt-tungsten (CoW) or a combination thereof, for example.

As shown in FIG. 10A, the first bonding pad 116A may be precisely aligned with the bonding metal layer 106 at the first bonding interface IS1, and the second bonding pad 146A may be precisely aligned with the bonding metal layer 106 at the second bonding interface IS2. Accordingly, the barrier layers 106B, 116A2, and 146A2 may be connected together to completely wrap the metal layers 106A, 116A1, and 146A1. In such embodiment, the barrier layers 106B, 116A2, and 146A2 may be referred to as a continuous barrier structure. However, the embodiments of the present invention are not limited thereto. In some other embodiments, as shown in FIG. 10B, the first bonding pad 116A may be laterally offset from the bonding metal layer 106 to expose a first portion P1 of the metal layer 106A at the first bonding interface IS1, and the second bonding pad 146A may be laterally offset from the bonding metal layer 106 to expose a second portion P2 of the metal layer 106A at the second bonding interface IS2. In this case, the barrier layer 106B would not be connect to the other barrier layers 116A2 and 146A2 to form a discontinuous barrier structure. In such embodiment, the bonding metal layer 106 may protrude from the sidewalls of the first bonding pad 116A and the second bonding pad 146A.

The middle layer disclosed herein is rather versatile, and may be applied to different types of package structures. The package structures with the middle layer in accordance with various embodiments will be described in detail below.

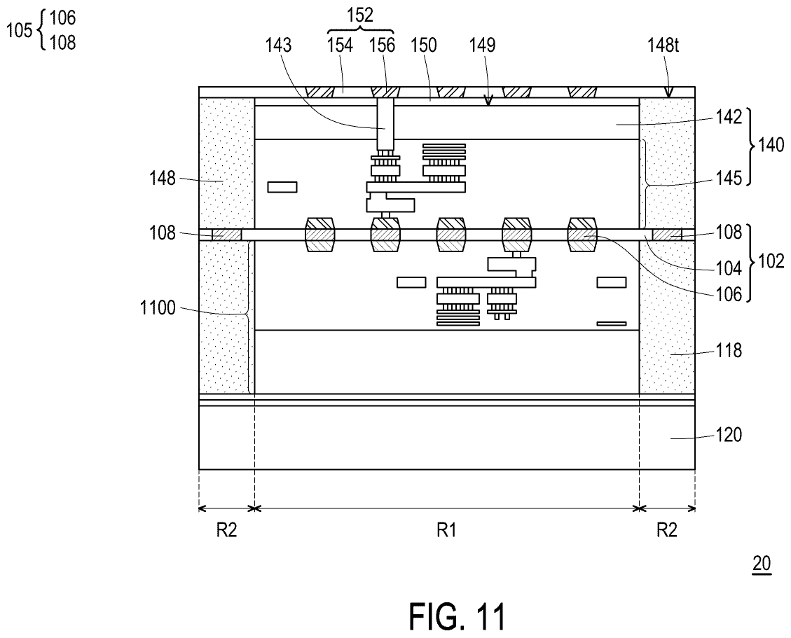

FIG. 11 illustrates a cross-sectional view of a package structure in accordance with some alternative embodiments.

Referring to FIG. 11, a package structure 20 is similar to the package structure 10 illustrated in FIG. 9, but the bottom dies 110 are replaced by a first die 1100 with large size. In some embodiments, the first die 1100 and the second die 140 have the same lateral width. Although only one first die 110 and one second die 140 are illustrated in FIG. 11, the embodiments of the present invention are not limited thereto. In other embodiments, the number of the first die 110 and the second die 140 can be adjusted by the needs.

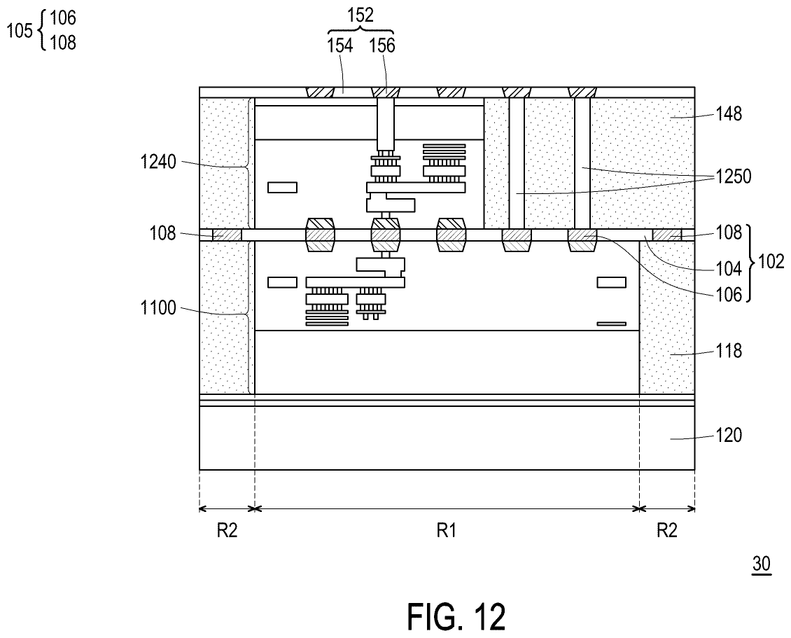

FIG. 12 illustrates a cross-sectional view of a package structure in accordance with some other embodiments.

Referring to FIG. 12, a package structure 30 is similar to the package structure 20 illustrated in FIG. 11, but the second die 140 is replaced by a second die 1240 with small size. In this case, there is space next to the second die 1240 to form one or more through dielectric vias (TDVs) 1250. In some embodiments, the TDVs 1250 may be disposed on the first die 1100 and aside the second die 1240 to penetrate through the second filling material 148 and connect the RDL structure 152 and the bonding metal layers 106 of the middle layer 102. As such, the TDVs 1250 may provide a vertical electrical path between the first die 1100 and the RDL structure 152 to increase the electrical signal transmission speed.

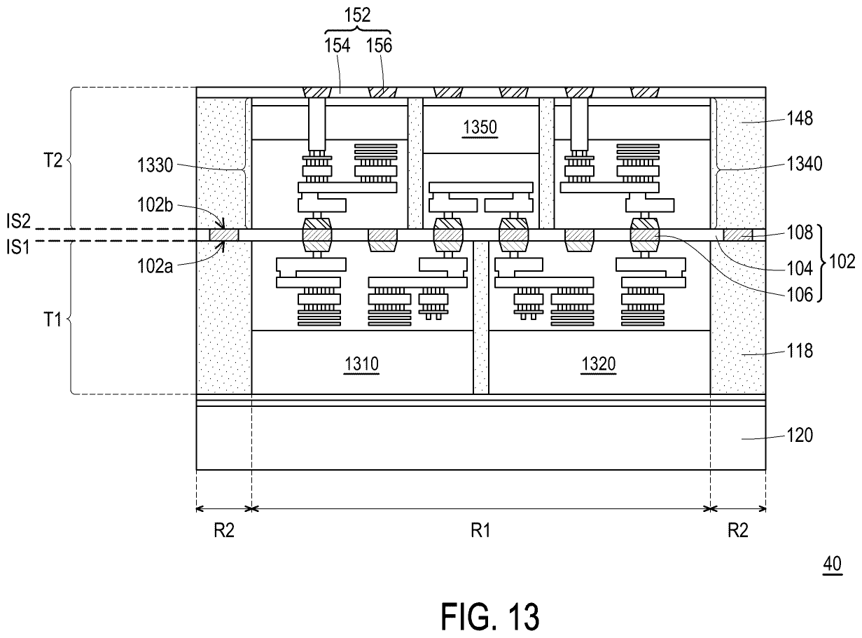

FIG. 13 illustrates a cross-sectional view of a package structure in accordance with some alternative embodiments.

Referring to FIG. 13, a package structure 40 is provided to include the middle layer 102, a first tier T1, and a second tier T2. The first tier T1 may be in contact with the first surface 102a of the middle layer 102 to define the first bonding interface IS1, and the second tier T2 may be in contact with the second surface 102b of the middle layer 102 to define the second bonding interface IS2. Specifically, the first tier T1 may include a first die 1310 and a second die 1320 disposed side by side, and the first filling material 118 laterally encapsulating the first die 1310 and the second die 1320. In some embodiments, one of the first die 1310 and the second die 1320 may be a logic die (e.g., central processing unit, mobile application processor, ASIC, GPU, FPGA, microcontroller, etc.), a memory die (e.g., dynamic random access memory (DRAM) die, a Wide I/O die, a M-RAM die, a R-RAM die, a NAND die, a static random access memory (SRAM) die, etc.), a memory cube (e.g., HBM, HMC, etc.), a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, signal processing dies (e.g., digital signal processing (DSP) die), a front-end die (e.g., analog front-end (AFE) dies), a monolithic 3D heterogeneous chiplet stacking die, the like, or a combination thereof. The first die 1310 and the second die 1320 may different functions or the same function.

In addition, the second tier T2 may include a third die 1330, a fourth die 1340, and a local silicon interconnect (LSI) die 1350 disposed side by side, and the second filling material 148 laterally encapsulating the third die 1330, the fourth die 1340, and the LSI die 1350. In some embodiments, the LSI die 1350 may be disposed between the third die 1330 and the fourth die 1340, and extend from the first die 1310 to the second die 1320 to electrically connect the first die 1310 and the second die 1320 via the bonding metal layers 106 of the middle layer 102. In detail, the LSI die 1350 may span the gap between the first die 1310 and the second die 1320 to interconnect the first die 1310 and the second die 1320, thereby allowing for greater die-to-die routing capacity. That is, compared with the related redistribution lines (RDLs), the LSI die 1350 has the greater routing density and transmission speed to achieve good bandwidth (BW) scalability and chip miniaturization. Accordingly, the LSI die 1350 can also be called a bridge or a bridge die.

In some alternative embodiments, the LSI die 1350 also has other functions other than interconnection. For example, the LSI die 1350 may have active and/or passive components, such as diodes, transistors, image sensors, capacitors, resistors, and so on. In some alternative embodiments, the LSI die 1350 includes a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

In some embodiments, one of the third die 1330 and the fourth die 1340 may be a logic die (e.g., central processing unit, mobile application processor, ASIC, GPU, FPGA, microcontroller, etc.), a memory die (e.g., dynamic random access memory (DRAM) die, a Wide I/O die, a M-RAM die, a R-RAM die, a NAND die, a static random access memory (SRAM) die, etc.), a memory cube (e.g., HBM, HMC, etc.), a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, signal processing dies (e.g., digital signal processing (DSP) die), a front-end die (e.g., analog front-end (AFE) dies), a monolithic 3D heterogeneous chiplet stacking die, the like, or a combination thereof. The third die 1330 and the fourth die 1340 may different functions or the same function.

In some other embodiments, the number of the die in the first tier T1 and/or the second tier T2 can be adjusted by the needs. For example, one of the third die 1330 and the fourth die 1340 may be replaced by one or more TDVs (as shown in FIG. 12), and the TDVs may penetrate through the second filling material 148 to connect the first die 1310 (or the second die 1320) and the RDL structure 152. Further, one of the third die 1330 and the fourth die 1340 may be replaced by a dummy die to improve the heat dissipation efficiency of the package structure.

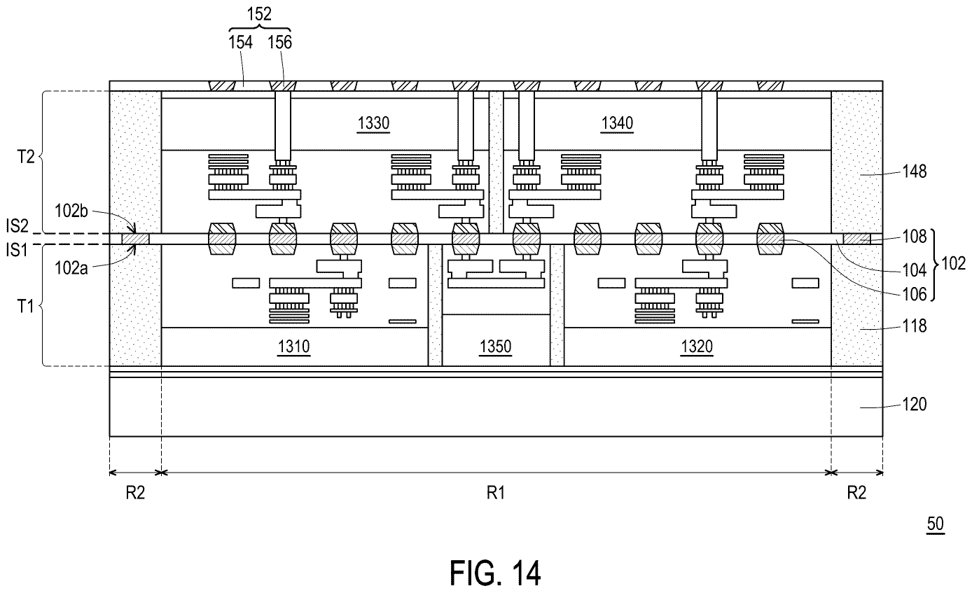

FIG. 14 illustrates a cross-sectional view of a package structure in accordance with some other embodiments.

Referring to FIG. 14, a package structure 50 is similar to the package structure 40 illustrated in FIG. 13, but the LSI die 1350 is moved from the second tier T2 to the first tier T1. Specifically, the LSI die 1350 may be disposed between the first die 1310 and the second die 1320, and extend from the third die 1330 to the fourth die 1340 to electrically connect the third die 1330 and the fourth die 1340 via the bonding metal layers 106 of the middle layer 102. That is, the LSI die 1350 may span the gap between the third die 1330 and the fourth die 1340 to interconnect the third die 1330 and the fourth die 1340, thereby allowing for greater die-to-die routing capacity. In such embodiment, one of the third die 1330 and the fourth die 1340 has a greater lateral width than that of the first die 1310 or the second die 1320.

According to some embodiments, a package structure includes a middle layer having a first surface and a second surface opposite to each other, a first die, and a second die. The middle layer includes a plurality of metal features. The first die is disposed on the first surface of the middle layer, wherein the first die includes a plurality of first bonding pads respectively contacting the plurality of metal features at the first surface to define a first bonding interface. The second die is disposed on the second surface of the middle layer, wherein the second die includes a plurality of second bonding pads respectively contacting the plurality of metal features at the second surface to define a second bonding interface.

According to some embodiments, a method of forming a package structure includes: forming a middle layer on a first carrier; bonding a frontside of the first die to a first surface of the middle layer to form a first bonding interface; bonding a second carrier to a backside of the first die opposite to the frontside; removing the first carrier and a portion of the middle layer so that a plurality of metal features of the middle layer are exposed at a second surface of the middle layer opposite to the first surface; and bonding a frontside of the second die to the second surface of the middle layer to form a second bonding interface.

According to some embodiments, a package structure includes a middle layer having a first surface and a second surface opposite to each other, a first tier, and a second tier. The middle layer includes a plurality of metal features. The first tier is in contact with the first surface of the middle layer to define a first bonding interface. The second tier is in contact with the second surface of the middle layer to define a second bonding interface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a middle layer having a first surface and a second surface opposite to each other, wherein the middle layer comprises a plurality of metal features;
a first die disposed on the first surface of the middle layer, wherein the first die comprises a plurality of first bonding pads respectively contacting the plurality of metal features at the first surface to define a first bonding interface; and
a second die disposed on the second surface of the middle layer, wherein the second die comprises a plurality of second bonding pads respectively contacting the plurality of metal features at the second surface to define a second bonding interface.

2. The package structure of claim 1, wherein one of the plurality of metal features comprises a metal layer and a barrier layer, and the barrier layer covers a sidewall of the metal layer without covering an upper surface and a lower surface of the metal layer.

3. The package structure of claim 2, wherein the one of the plurality of metal features is laterally offset from a respective first bonding pad so that a first portion of the metal layer is exposed at the first surface, and the one of the plurality of metal features is laterally offset from a respective second bonding pad so that a second portion of the metal layer is exposed at the second surface.

4. The package structure of claim 3, further comprising:
a first filling material disposed on the first surface of the middle layer to laterally encapsulate the first die;
a second filling material disposed on the second surface of the middle layer to laterally encapsulate the second die; and
a redistribution layer (RDL) structure disposed on the second die and the second filling material to electrically connect the first die via through-substrate vias (TSVs) and an interconnect structure of the second die and the plurality of metal features of the middle layer.

5. The package structure of claim 4, wherein the middle layer comprises a die attach region and a peripheral region surrounding the die attach region, and the plurality of metal features comprises:
a plurality of bonding metal layers disposed within the die attach region of the middle layer; and
at least one alignment mark disposed within the peripheral region of the middle layer.

6. The package structure of claim 5, wherein the at least one alignment mark is in contact with the first fill material at the first surface, and in contact with the second fill material at the second surface.

7. The package structure of claim 4, further comprising:
a plurality of through dielectric vias (TDVs) disposed on the first die and aside the second die to penetrate through the second filling material and connect the RDL structure and the plurality of metal features.

8. The package structure of claim 1, further comprising:
a dummy die disposed side by side with the first die, wherein the first die and the dummy die are within a span of the second die.

9. The package structure of claim 1, wherein the first die and the second die have substantially same lateral width.

10. A method of forming a package structure, comprising:
forming a middle layer on a first substrate;
bonding a first side of the first die to a first surface of the middle layer to form a first bonding interface;
bonding a second substrate to a second side of the first die opposite to the first side;
removing the first substrate and a portion of the middle layer so that a plurality of metal features of the middle layer are exposed at a second surface of the middle layer opposite to the first surface; and
bonding a first side of the second die to the second surface of the middle layer to form a second bonding interface.

11. The method of claim 10, wherein the middle layer comprises a plurality of metal features, the plurality of metal features are respectively in contact with a plurality of first bonding pads of the first die at the first bonding interface, and the plurality of metal features are respectively in contact with a plurality of second bonding pads of the second die at the second bonding interface.

12. The method of claim 11, wherein the middle layer comprises a die attach region and a peripheral region surrounding the die attach region, and the plurality of metal features comprises:
a plurality of bonding metal layers formed within the die attach region of the middle layer; and
at least one alignment mark formed within the peripheral region of the middle layer.

13. The method of claim 12, wherein the bonding of the first die and the second die is aligned through the at least one alignment mark.

14. The method of claim 10, wherein before bonding the second substrate to the second side of the first die, the method further comprises: forming a first filling material to laterally encapsulate the first die.

15. The method of claim 10, wherein after bonding the first side of the second die to the second surface of the middle layer, the method further comprises: forming a second filling material to laterally encapsulate the second die.

16. The method of claim 15, further comprising: forming a redistribution layer (RDL) structure on a second side of the second die and the second filling material.

17. A package structure, comprising:
a middle layer having a first surface and a second surface opposite to each other, wherein the middle layer comprises a plurality of metal features, and one of the plurality of metal features comprises a metal layer and a barrier layer, and the barrier layer covers a sidewall of the metal layer without covering an upper surface and a lower surface of the metal layer;
a first tier contacting the first surface of the middle layer to define a first bonding interface; and
a second tier contacting the second surface of the middle layer to define a second bonding interface.

18. The package structure of claim 17, wherein the middle layer comprises a die attach region and a peripheral region surrounding the die attach region, and the plurality of metal features comprises:
a plurality of bonding metal layers disposed within the die attach region of the middle layer; and
at least one alignment mark disposed within the peripheral region of the middle layer.

19. The package structure of claim 17,
wherein the first tier comprises:
a first die and a second die disposed side by side; and
a first filling material laterally encapsulating the first and second dies; and
wherein the second tier comprises:
a third die, a fourth die, and a bridge disposed side by side, wherein the bridge is disposed between the third die and the fourth die, and extends from the first die to the second die to electrically connect the first die and the second die via the plurality of metal features; and
a second filling material laterally encapsulating the third die, the fourth die, and the bridge.

20. The package structure of claim 17,
wherein the first tier comprises:
a first die, a second die, and a bridge disposed side by side, wherein the bridge is disposed between the first die and the second die; and
a first filling material laterally encapsulating the first die, the second die, and the bridge; and
wherein the second tier comprises:
a third die and a fourth die disposed side by side, wherein the bridge extends from the third die to the fourth die to electrically connect the third die and the fourth die via the plurality of metal features; and
a second filling material laterally encapsulating the third die and the fourth die.
